(19) United States
(12) Patent Application Publication
(10) Pub. No.: US 2022/0262781 A1
(43) Pub. Date: Aug. 18, 2022

(54) DISPLAY DEVICE

(71) Applicant: Samsung Display Co., Ltd., Yongin-si (KR)

(72) Inventors: Jae Been LEE, Seoul (KR); Yi Joon AHN, Seoul (KR)

(21) Appl. No.: 17/670,804

(22) Filed: Feb. 14, 2022

(30) Foreign Application Priority Data
Feb. 15, 2021 (KR) 10-2021-0019822

(51) Int. Cl. H01L 25/16

(52) U.S. Cl. CPC H01L 25/167; H01L 24/25; H01L 25/162

(57) ABSTRACT

A display device includes a display area including a plurality of pixels arranged in a first direction and a second direction intersecting the first direction, each of the plurality of pixels including light-emitting area groups and non-light-emitting areas disposed adjacent to the light-emitting area groups, and a non-display area surrounding the display area, where a minimum distance between adjacent ones of the light-emitting area groups continuously arranged along the first direction or the second direction increases and decreases repeatedly.

This application claims priority to Korean Patent Application No. 10-2021-0019822, filed on Feb. 15, 2021, and all the benefits accruing therefrom under 35 U.S.C. § 119, the content of which in its entirety is herein incorporated by reference.

### BACKGROUND

### 1. Field

Embodiments of the invention relate to a display device.

### 2. Description of the Related Art

As an information-oriented society evolves, various demands for display devices are ever increasing. The display devices are being employed by a variety of electronic devices such as smart phones, digital cameras, laptop computers, navigation devices, and smart televisions. The display devices may be flat panel display devices such as a liquid-crystal display device, a field emission display device, and an organic light-emitting display device. Among such flat panel display devices, a light-emitting display device includes a light-emitting element that may emit light on its own, so that each of the pixels of the display panel may emit light by themselves. Accordingly, a light-emitting display device may display images without a backlight unit that supplies light to the display panel.

For a display device having a large screen, a large number of pixels is disposed, and thus a defect rate of light-emitting elements may increase while productivity or reliability may deteriorate. To overcome such issues, a tiled display may provide a large screen by connecting a plurality of display devices having a relatively small size. Such a tiled display may include boundaries between the plurality of display devices which are referred to as seams because there are the non-display areas or bezel areas between the plurality of display devices adjacent to each other.

### SUMMARY

When a single image is displayed on a full screen, boundaries between the display devices result in visible seams, hindering a viewer from getting immersed into the image.

Features of the invention provide a display that eliminates visible seams between a plurality of display devices by way of preventing the boundaries between the display devices from being perceived so that a viewer may be immersed into displayed images.

It should be noted that features of the invention are not limited to the above-mentioned object, and other features of the invention will be apparent to those skilled in the art from the following descriptions.

The details of embodiments of the subject matter described in this specification are set forth in the accompanying drawings and the description below.

In an embodiment, a display device includes a display area including a plurality of pixels arranged in a first direction and a second direction intersecting the first direction, each of the plurality of pixels including light-emitting area groups and non-light-emitting areas disposed adjacent to the light-emitting area groups, and a non-display area surrounding the display area, where a minimum distance between adjacent ones of the light-emitting area groups continuously arranged along the first direction or the second direction increases and decreases repeatedly.

In another embodiment, a display device includes a first display device, a second display device disposed on one side of the first display device, and a sealing member disposed between the first display device and the second display device and coupling the first display device with the second display device, where each of the first display device and the second display device includes a display area including a plurality of pixels arranged in a first direction and a second direction intersecting the first direction, each of the plurality of pixels including light-emitting area groups and non-light-emitting areas disposed adjacent to the light-emitting area groups, and a non-display area surrounding the display area, where a minimum distance between adjacent ones of the light-emitting area groups continuously arranged along the first direction or the second direction increases and decreases repeatedly.

By embodiments of the invention, a tiled display may allow a viewer to get immersed into the images by eliminating visual seams between the display devices by way of preventing the non-display area or boundaries between the display devices from being perceived by the viewer.

It should be noted that effects of the invention are not limited to those described above and other effects of the invention will be apparent to those skilled in the art from the following descriptions.

### BRIEF DESCRIPTION OF THE DRAWINGS

The above and other embodiments and features of the invention will become more apparent by describing in detail embodiments thereof with reference to the attached drawings, in which:

FIG. 1 is a plan view showing an embodiment of a tiled display according to the invention.

FIG. 2A is an enlarged plan view of a periphery of the coupling area between the display devices of the tiled display of FIG. 1, and FIG. 2B is an enlarged plan view of a portion of FIG. 2A.

FIG. 3 is a cross-sectional view of the enlarged view of FIG. 2B, taken along line I-I′.

FIG. 4 is a plan view showing an embodiment of a pixel of a display device according to the invention.

FIG. 5A is a cross-sectional view taken along line II-II′ of FIG. 4, and FIG. 5B is an enlarged plan view of a portion of FIG. 5A.

FIG. 6 is a view showing an embodiment of a light-emitting element according to the invention.

FIG. 7 is an enlarged plan view of area A of FIG. 1.

FIG. 8 is a schematic view showing an embodiment of layouts between light-emitting areas and transistor areas of pixels according to the invention.

FIG. 9 is a plan view showing an embodiment of FIG. 7.

FIG. 10 is an enlarged plan view of area B of FIG. 1.

FIG. 11 is a plan view showing an embodiment of FIG. 10.

FIG. 12 is a plan view showing another embodiment of FIG. 10.

FIG. 13 is a plan view showing yet another embodiment of FIG. 10.

FIG. 14 is a table showing coefficients of Equation of distances between adjacent light-emitting area groups versus the number of pixels of FIGS. 11 to 13.

FIG. 15 is a plan view showing another embodiment of FIG. 9.

FIG. 16 is a schematic view showing adjusting the luminance of light-emitting area groups adjacent to a boundary between display devices.

FIG. 17A is a plan view showing an embodiment of a layout of a second light-emitting area of a light-emitting area group, and FIG. 17B is an enlarged plan view of a portion of FIG. 17A.

FIG. 18 is a plan view showing an example where a sensor is employed.

### DETAILED DESCRIPTION

Specific structural and functional descriptions of embodiments of the invention disclosed herein are only for illustrative purposes of the embodiments of the invention. The invention may be embodied in many different forms without departing from the spirit and significant characteristics of the invention. Therefore, the embodiments of the invention are disclosed only for illustrative purposes and should not be construed as limiting the invention. That is, the invention is only defined by the scope of the claims.

It will be understood that when an element is referred to as being related to another element such as being “coupled” or “connected” to another element, it can be directly coupled or connected to the other element or intervening elements may be present therebetween. In contrast, it should be understood that when an element is referred to as being related to another element such as being “directly coupled” or “directly connected” to another element, there are no intervening elements present. Other expressions that explain the relationship between elements, such as “between,” “directly between,” “adjacent to,” or “directly adjacent to,” should be construed in the same way.

Throughout the specification, the same reference numerals will refer to the same or like parts.

It will be understood that, although the terms “first,” “second,” “third” etc. may be used herein to describe various elements, components, regions, layers and/or sections, these elements, components, regions, layers and/or sections should not be limited by these terms. These terms are only used to distinguish one element, component, region, layer or section from another element, component, region, layer or section. Thus, “a first element,” “component,” “region,” “layer” or “section” discussed below could be termed a second element, component, region, layer or section without departing from the teachings herein.

The terminology used herein is for the purpose of describing particular embodiments only and is not intended to be limiting. As used herein, “a”, “an,” “the,” and “at least one” do not denote a limitation of quantity, and are intended to include both the singular and plural, unless the context clearly indicates otherwise. For example, “an element” has the same meaning as “at least one element,” unless the context clearly indicates otherwise. “At least one” is not to be construed as limiting “a” or “an.” “Or” means “and/or.” As used herein, the term “and/or” includes any and all combinations of one or more of the associated listed items. It will be further understood that the terms “comprises” and/or “comprising,” or “includes” and/or “including” when used in this specification, specify the presence of stated features, regions, integers, steps, operations, elements, and/or components, but do not preclude the presence or addition of one or more other features, regions, integers, steps, operations, elements, components, and/or groups thereof

Furthermore, relative terms, such as “lower” or “bottom” and “upper” or “top,” may be used herein to describe one element's relationship to another element as illustrated in the drawing figures. It will be understood that relative terms are intended to encompass different orientations of the device in addition to the orientation depicted in the drawing figures. For example, if the device in one of the drawing figures is turned over, elements described as being on the “lower” side of other elements would then be oriented on “upper” sides of the other elements. The exemplary term “lower,” can therefore, encompasses both an orientation of “lower” and “upper,” depending on the particular orientation of the figure. Similarly, if the device in one of the drawing figures is turned over, elements described as “below” or “beneath” other elements would then be oriented “above” the other elements. The exemplary terms “below” or “beneath” can, therefore, encompass both an orientation of above and below.

“About” or “approximately” as used herein is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” can mean within one or more standard deviations, or within ±30%, 20%, 10% or 5% of the stated value.

Unless otherwise defined, all terms (including technical and scientific terms) used herein have the same meaning as commonly understood by one of ordinary skill in the art to which this disclosure belongs. It will be further understood that terms, such as those defined in commonly used dictionaries, should be interpreted as having a meaning that is consistent with their meaning in the context of the relevant art and the disclosure, and will not be interpreted in an idealized or overly formal sense unless expressly so defined herein.

Embodiments are described herein with reference to cross section illustrations that are schematic illustrations of idealized embodiments. As such, variations from the shapes of the illustrations as a result, for example, of manufacturing techniques and/or tolerances, are to be expected. Thus, embodiments described herein should not be construed as limited to the particular shapes of regions as illustrated herein but are to include deviations in shapes that result, for example, from manufacturing. For example, a region illustrated or described as flat may, typically, have rough and/or nonlinear features. Moreover, sharp angles that are illustrated may be rounded. Thus, the regions illustrated in the drawing figures are schematic in nature and their shapes are not intended to illustrate the precise shape of a region and are not intended to limit the scope of the claims.

Hereinafter, embodiments of the invention will be described in detail with reference to the accompanying drawings.

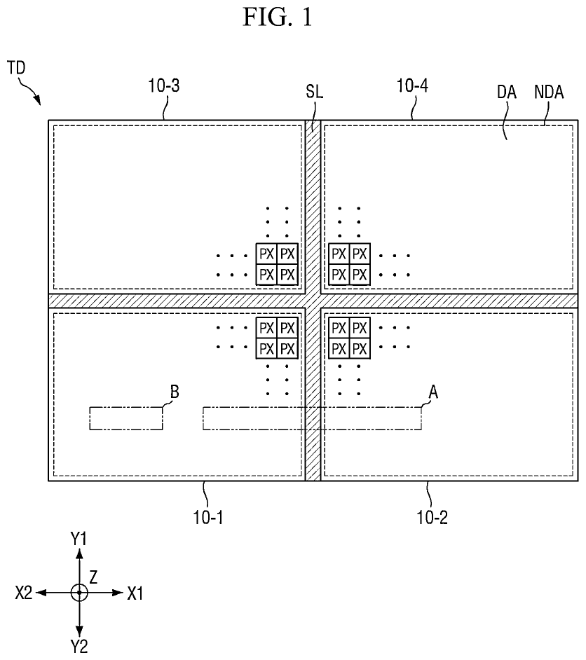

FIG. 1 is a plan view showing an embodiment of a tiled display according to the invention.

Referring to FIG. 1, a tiled display device TD may have a quadrangular (e.g., rectangular) shape when viewed from the top. It is, however, to be understood that the invention is not limited thereto. The shape of the tiled display device TD when viewed from the top may have a square, a circle, an ellipse, or other polygons. In the following description, the tiled display device TD has a quadrangular (e.g., rectangular) shape when viewed from the top. The tiled display device TD having a quadrangular (e.g., rectangular) shape when viewed from the top may include longer sides extended in a first direction X1 and X2 and shorter sides extended in a second direction Y1 and Y2. The corners where the longer side and the shorter side of the tiled display device TD meet may be formed or provided at the right angle as shown in FIG. 1, but the invention is not limited thereto. The corners may be rounded.

The tiled display device TD may refer to a large display apparatus in which a plurality of display devices is arranged in a lattice pattern and adjacent display devices are combined at a coupling area. In other words, the tiled display device TD may include a plurality of display devices. The plurality of display devices may be connected in the first direction X1 and X2 or the second direction Y1 and Y2, and the tiled display device TD may have a predetermined shape. In an embodiment, the plurality of display devices may all have the same size, for example. It is, however, to be understood that the invention is not limited thereto. In another embodiment, the display devices may have different sizes from each other, for example. In an embodiment, each of the plurality of display devices may have a quadrangular (e.g., rectangular) shape including longer sides and shorter sides, for example. The plurality of display devices may be arranged such that the longer sides or the shorter sides of the display devices are connected with one another. Some of the display devices may be disposed on an edge of the tiled display device TD to form one side of the tiled display device TD. Some of the display devices may be disposed at a corner of the tiled display device TD, and may form two adjacent sides of the tiled display device TD. Some of the others of the display devices may be disposed on the inner side of the tiled display device TD and may be surrounded by the other display devices.

In the following description, the tiled display device TD includes four display devices for convenience of illustration. Specifically, the tiled display device TD may include a first display device 10-1, a second display device 10-2 disposed on one side (e.g., right side in FIG. 1) of the first display device 10-1 in the first direction X1, a third display device 10-3 disposed on one side (e.g., upper side in FIG. 1) of the first display device 10-1 in the second direction Yl, and a fourth display device 10-4 disposed on one side (e.g., right side in FIG. 1) of the third display device 10-3 in the first direction Xl.

Hereinafter, the first display device 10-1 will be described while the other display devices 10-2, 10-3 and 10-4 will not be described in detail unless they have to be distinguished from the first display device 10-1. The display devices 10-2, 10-3 and 10-4 will be described wherever it is necessary to distinguish them from the first display device 10-1.

The first display device 10-1 may include a display area DA and a non-display area NDA. The display area DA may include a plurality of pixels PX to display images. The plurality of pixels PX may be arranged in a matrix pattern. The non-display area NDA may be disposed around the display area DA to surround the display area DA, and may display no image. The non-display area NDA may completely surround the display area DA when viewed from the top.

The plurality of display devices 10-1 to 10-4 is connected with one another by a connecting member. The connecting member may include, but is not limited to, a sealing member SL. In the tiled display device TD including the first to fourth display devices 10-1 to 10-4, the sealing member SL is disposed at boundaries between the display devices 10-1 to 10-4 when viewed from the top. In an embodiment, the sealing member SL may be disposed between the non-display area NDA of the first display device 10-1 and the non-display area NDA of the second display 10-2 to combine the first display device 10-1 with the second display device 10-2, may be disposed between the non-display area NDA of the first display device 10-1 and the non-display area NDA of the third display 10-3 to combine the first display device 10-1 with the third display device 10-3, may be disposed between the non-display area NDA of the third display device 10-3 and the non-display area NDA of the fourth display 10-4 to combine the third display device 10-3 with the fourth display device 10-4, and may be disposed between the non-display area NDA of the fourth display device 10-4 and the non-display area NDA of the second display 10-2 to combine the fourth display device 10-4 with the second display device 10-2, for example.

The sealing member SL may be continuously disposed. Specifically, the sealing member SL may be extended in the first direction X1 and X2 and the second direction Y1 and Y2, and may include portions intersecting in the first direction X1 and X2 and the second direction Y1 and Y2.

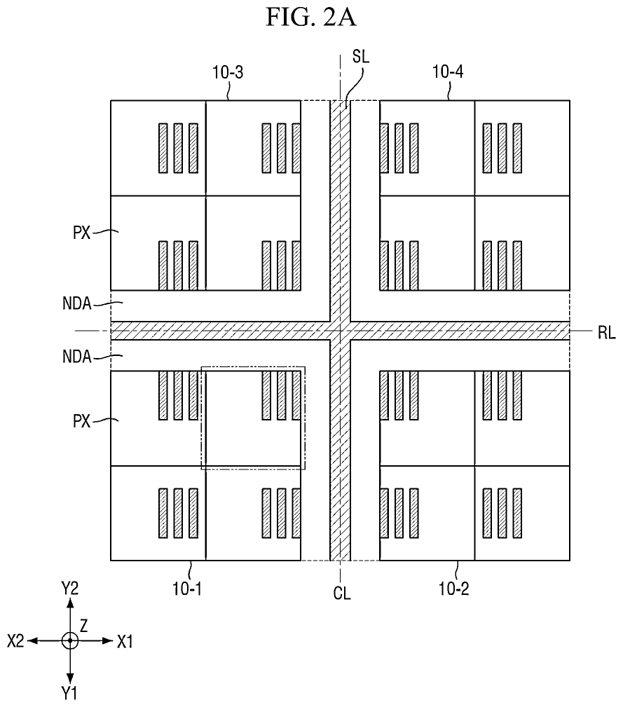

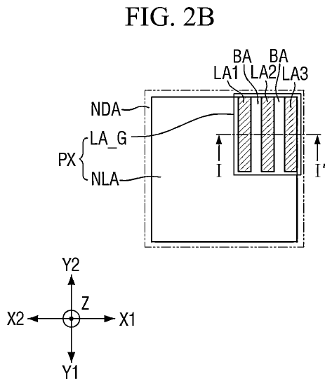

FIG. 2A is an enlarged plan view of a periphery of the coupling area between the display devices of the tiled display of FIG. 1 and FIG. 2B is an enlarged plan view of a portion of FIG. 2A.

Referring to FIGS. 2A and 2B, each of the plurality of pixels PX of the display devices 10-1 to 10-4 may include light-emitting areas LA1, LA2 and LA3 defined by a pixel-defining layer, and may emit light having a predetermined peak wavelength through the light-emitting areas LA1, LA2 and LA3. In an embodiment, the display area DA of each of the display devices may include first to third light-emitting areas LA1, LA2 and LA3, for example. In each of the first to third light-emitting areas LA1, LA2 and LA3, light generated by light-emitting elements of the display devices exits out of the display devices.

The first to third light-emitting areas LA1, LA2 and LA3 may emit light having predetermined peak wavelengths to the outside of the display devices. The first light-emitting area LA1 may emit light of a first color, the second light-emitting area LA2 may emit light of a second color, and the third light-emitting area LA3 may emit light of a third color. In an embodiment, the light of the first color may be red light having a peak wavelength in the range of about 610 nanometers (nm) to about 650 nm, the light of the second color may be green light having a peak wavelength in the range of about 510 nm to about 550 nm, and the light of the third color may be blue light having a peak wavelength in the range of about 440 nm to about 480 nm, for example. It is, however, to be understood that the invention is not limited thereto.

The first to third light-emitting areas LA1, LA2 and LA3 may be arranged repeatedly and sequentially along the first direction X1 and X2 of the display area DA. In an embodiment, the width of the first light-emitting area LA1 in the first direction X1 and X2 may be larger than the width of the second light-emitting area LA2 in the first direction X1 and X2, for example. The width of the second light-emitting area LA2 in the first direction X1 and X2 may be larger than the width of the third light-emitting area LA3 in the first direction X1 and X2. In another embodiment, the width of the first light-emitting area LA1 in the first direction Xl and X2, the width of the second light-emitting area LA2 in the first direction X1 and X2, and the width of the third light-emitting area LA3 in the first direction X1 and X2 may be substantially the same as each other, for example.

In an embodiment, the area of the first light-emitting area LA1 may be greater than the area of the second light-emitting area LA2, and the area of the second light-emitting area LA2 may be greater than the area of the third light-emitting area LA3, for example. In another embodiment, the area of the first light-emitting area LA1, the area of the second light-emitting area LA2 and the area of the third light-emitting area LA3 may be substantially the same as each other, for example.

The display areas DA of the display devices may include light-blocking areas BA disposed between the adjacent ones of the light-emitting areas LA1, LA2 and LA3. In an embodiment, the light-blocking areas BA may be disposed between the first light-emitting area LA1 and the second light-emitting area LA2 and between the second light-emitting area LA2 and the third light-emitting area LA3, respectively, for example.

The light-emitting areas LA1, LA2 and LA3 and the light-blocking areas BA disposed between adjacent ones of the light-emitting areas LA1, LA2 and LA3 may form a light-emitting area group LA_G. The pixel PX may include a non-light-emitting area NLA surrounding the light-emitting area group LA_G. The light-emitting area group LA_G may be distinguished from the non-light-emitting area NLA by the outer profiles of the light-emitting areas LA1, LA2 and LA3 and the light-blocking areas BA between the adjacent ones of the light-emitting areas LA1, LA2 and LA3.

The layout of the light-emitting area groups LA_G of the first display device 10-1 may be symmetrical to the layout of the light-emitting area groups LA_G of the fourth display device 10-4, and the layout of the light-emitting area groups LAG of the second display device 10-2 may be symmetrical to the layout of the light-emitting area groups LA_G of the third display device 10-3.

Prior to describing the layout of the light-emitting area groups LA_G, a cross-sectional structure of the light-emitting area groups LA_G will be described.

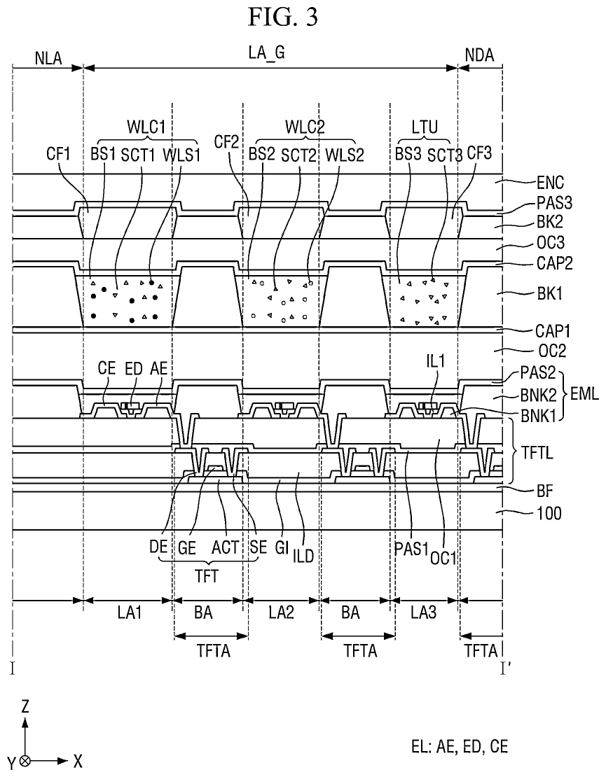

FIG. 3 is a cross-sectional view of the enlarged view of FIG. 2A, taken along line I-I′.

Referring to FIG. 3, the display area DA (refer to FIG. 1) of each of the display devices may include first to third light-emitting areas LA1, LA2, and LA3. In each of the first to third light-emitting areas LA1, LA2 and LA3, light generated by light-emitting elements of the display devices exits out of the display devices.

Each of the display devices may include a substrate 100, a buffer layer BF, a thin-film transistor layer TFTL, and an emission material layer EML.

The substrate 100 may be a base substrate or a base member and may include an insulating material such as a polymer resin. In an embodiment, the substrate 100 may be a rigid substrate, for example.

The buffer layer BF may be disposed on the substrate 100. The buffer layer BF may include an inorganic film that may prevent the permeation of air or moisture.

The thin-film transistor layer TFTL may include a thin-film transistor TFT, a gate insulating layer GI, an interlayer dielectric film ILD, a first passivation layer PAS1, and a first planarization layer OC1.

The thin-film transistor TFT may be disposed on the buffer layer BF, and may form a pixel circuit of each of a plurality of pixels. The thin-film transistor TFT may include a semiconductor layer ACT, a gate electrode GE, a source electrode SE, and a drain electrode DE, which will be described later. Moreover, as shown in FIG. 3, the area in which the thin-film transistor TFT including the semiconductor layer ACT, the gate electrode GE, the source electrode SE and the drain electrode DE is disposed is referred to as a thin-film transistor area TFTA.

The semiconductor layer ACT may be disposed on the buffer layer BF. The semiconductor layer ACT may overlap the gate electrode GE, the source electrode SE and the drain electrode DE. The semiconductor layer ACT may be in direct contact with the source electrode SE and the drain electrode DE, and may face the gate electrode GE with the gate insulating layer GI therebetween.

The gate electrode GE may be disposed on the gate insulating layer GI. The gate electrode GE may overlap the semiconductor layer ACT with the gate insulating layer GI interposed therebetween.

The source electrode SE and the drain electrode DE are disposed on the interlayer dielectric film ILD such that they are spaced apart from each other. The source electrode SE may be in contact with one end of the semiconductor layer ACT through a contact hole defined in the gate insulating layer GI and the interlayer dielectric film ILD. The drain electrode DE may be in contact with the other end of the semiconductor layer ACT through a contact hole defined in the gate insulating layer GI and the interlayer dielectric film ILD. The drain electrode DE may be connected to a first electrode AE of a light-emitting element EL through a contact hole defined in the first passivation layer PAS1 and the first planarization layer OC1.

The above-described thin-film transistor area TFTA may substantially overlap with the light-blocking area BA in the thickness direction (e.g., Z direction in FIG. 3).

The gate insulating layer GI may be disposed on the semiconductor layer ACT. In an embodiment, the gate insulating layer GI may be disposed on the semiconductor layer ACT and the buffer layer BF, and may insulate the semiconductor layer ACT from the gate electrode GE, for example. A contact hole in which the source electrode SE is disposed and a contact hole in which the drain electrode DE is disposed may be defined in the gate insulating layer GI.

The interlayer dielectric film ILD may be disposed over the gate electrode GE. In an embodiment, the contact hole in which the source electrode SE is disposed, and the contact hole in which the drain electrode DE is disposed may be defined in the interlayer dielectric film ILD, for example.

The first passivation layer PAS1 may be disposed above the thin-film transistor TFT to protect the thin-film transistor TFT. In an embodiment, a contact hole in which the first electrode AE is disposed may be defined in the first passivation layer PAS1, for example.

The first planarization layer OC1 may be disposed on the first passivation layer PAS1 to provide a flat surface over the thin-film transistor TFT. In an embodiment, a contact hole in which the first electrode AE of the light-emitting element EL is disposed may be defined in the first planarization layer OC1, for example.

The emission material layer EML may include a light-emitting element EL, a first bank BNK1, a second bank BNK2, and a second passivation layer PAS2.

The light-emitting element EL may be disposed on the thin-film transistor TFT. The light-emitting element EL may include a first electrode AE, a second electrode CE, and a light-emitting diode ED.

The first electrode AE may be disposed on the first planarization layer OC1. In an embodiment, the first electrode AE may be disposed over the first bank BNK1 disposed on the first planarization layer OC1 to cover the first bank BNK1, for example. The first electrode AE may be disposed to overlap one of the first to third light-emitting areas LA1, LA2 and LA3 defined by the second bank BNK2. The first electrode AE may be connected to the drain electrode DE of the thin-film transistor TFT.

The second electrode CE may be disposed on the first planarization layer OC1. In an embodiment, the second electrode CE may be disposed over the first bank BNK1 disposed on the first planarization layer OC1 to cover the first bank BNK1, for example. The second electrode CE may be disposed to overlap one of the first to third light-emitting areas LA1, LA2 and LA3 defined by the second bank BNK2. In an embodiment, the second electrode CE may receive a common voltage applied to all pixels, for example.

The first insulating layer IL1 may cover a part of the first electrode AE and a part of the second electrode CE adjacent to each other and may insulate the first and second electrodes AE and CE from each other.

The light-emitting diode ED may be disposed between the first electrode AE and the second electrode CE above the first planarization layer OC1. The light-emitting diode ED may be disposed on the first insulating layer IL1. One end of the light-emitting diode ED may be connected to the first electrode AE, and the other end of the light-emitting diode ED may be connected to the second electrode CE. In an embodiment, the plurality of light-emitting diodes ED may include active layers having the same material as each other so that they may emit light of the same wavelength or light of the same color as each other, for example. The lights emitted from the first to third light-emitting areas LA1, LA2 and LA3, respectively, may have the same color. In an embodiment, the plurality of light-emitting diodes ED may emit light of the third color or blue light having a peak wavelength in the range of about 440 nm to about 480 nm, for example.

The second bank BNK2 may be disposed on the first planarization layer OC1 to define first to third light-emitting areas LA1, LA, and LA3. In an embodiment, the second bank BNK2 may surround each of the first to third light-emitting areas LA1, LA2 and LA3, for example. It is, however, to be understood that the invention is not limited thereto. The second bank BNK2 may be disposed in each of the light-blocking areas BA.

The second passivation layer PAS2 may be disposed on the plurality of light-emitting elements EL and the second bank BNK2. The second passivation layer PAS2 may cover the plurality of light-emitting elements EL to protect the plurality of light-emitting elements EL.

The display device may further include a second planarization layer OC2, a first capping layer CAP1, a first light-blocking member BK1, a first wavelength-converting unit WLC1, a second wavelength-converting unit WLC2, a light-transmitting unit LTU, a second capping layer CAP2, a third planarization layer OC3, a second light-blocking member BK2, first to third color filters CF1, CF2 and CF3, a third passivation layer PAS3, and encapsulation layer ENC.

The second planarization layer OC2 may be disposed on the emission material layer EML to provide a flat surface over the emission material layer EML. The second planarization layer OC2 may include an organic material.

The first capping layer CAP1 may be disposed on the second planarization layer OC2. The first capping layer CAP1 may seal the lower surfaces of the first and second wavelength-converting units WLC1 and WLC2 and the light-transmitting unit LTU. The first capping layer CAP1 may include an inorganic material.

The first light-blocking member BK1 may be disposed on the first capping layer CAP1 in the light-blocking area BA. The first light-blocking member BK1 may overlap the second bank BNK2 in the thickness direction. The first light-blocking member BK1 may block the transmission of light.

The first light-blocking member BK1 may include an organic light-blocking material and a liquid repellent component.

Since the first light-blocking member BK1 includes the liquid repellent component, the first and second wavelength-converting units WLC1 and WLC2 and the light-transmitting unit LTU may be separated so that they may correspond to the respective light-emitting areas LA1, LA2, LA3.

The first wavelength-converting unit WLC1 may be disposed in the first light-emitting area LA1 on the first capping layer CAP1. The first wavelength-converting unit WLC1 may be surrounded by the first light-blocking member BK1. The first wavelength-converting unit WLC1 may include a first base resin BS1, first scatterers SCT1, and first wavelength shifters WLS1.

The first base resin BS1 may include a material having a relatively high light transmittance. The first base resin BS1 may include a transparent organic material. In an embodiment, the first base resin BS1 may include at least one organic material among an epoxy resin, an acrylic resin, a cardo resin, and an imide resin, for example.

The first scatterers SCT1 may have a refractive index different from that of the first base resin BS1 and may form an optical interface with the first base resin BS1.

The first wavelength shifters WLS1 may convert or shift the peak wavelength of the incident light to a first peak wavelength. In an embodiment, the first wavelength shifters WLS1 may convert blue light provided from the display device into red light having a single peak wavelength in the range of about 610 nm to about 650 nm, and output the light, for example. The first wavelength shifters WLS1 may be quantum dots, quantum rods, or phosphor. The quantum dots may be particulate matter that emits a color as electrons transition from the conduction band to the valence band.

The light output from the first wavelength shifters WLS1 may have a full width of half maximum (“FWHM”) of the emission wavelength spectrum of about 45 nm or less, about 40 nm or less, or about 30 nm or less. In this manner, the color purity and color gamut of the colors displayed by the display device may be further improved.

A part of the blue light emitted from the emission material layer EML may pass through the first wavelength-converting unit WLC1 without being converted into red light by the first wavelength shifters WLS1. When such blue light is incident on the first color filter CF1, it may be blocked by the first color filter CF1. Red light converted by the first wavelength-converting unit WLC1 may pass through the first color filter CF1 to exit to the outside. Accordingly, the first light-emitting area LA1 may emit red light.

The second wavelength-converting unit WLC2 may be disposed in the second light-emitting area LA2 on the first capping layer CAP1. The second wavelength-converting unit WLC2 may be surrounded by the first light-blocking member BK1. The second wavelength-converting unit WLC2 may include a second base resin BS2, second scatterers SCT2, and second wavelength shifters WLS2.

The second base resin BS2 may include a material having a relatively high light transmittance. The second base resin BS2 may include a transparent organic material.

The second scatterers SCT2 may have a refractive index different from that of the second base resin BS2 and may form an optical interface with the second base resin BS2. In an embodiment, the second scatterers SCT2 may include a light scattering material or light scattering particles that scatter at least a part of transmitted light, for example.

The second wavelength shifters WLS2 may convert or shift the peak wavelength of the incident light to a second peak wavelength that is different from the first peak wavelength of the first wavelength shifters WLS1. In an embodiment, the second wavelength shifters WLS2 may convert blue light provided from the display device into green light having a single peak wavelength in the range of about 510 nm to about 550 nm, and output the light, for example. The second wavelength shifters WLS2 may be quantum dots, quantum rods, or phosphor. The second wavelength shifters WLS2 may include the above-listed materials of the first wavelength shifters WLS1.

The light-transmitting unit LTU may be disposed in the third light-emitting area LA3 on the first capping layer CAP1. The light-transmitting unit LTU may be surrounded by the first light-blocking member BK1. The light-transmitting unit LTU may transmit the incident light without converting its peak wavelength. The light-transmitting unit LTU may include a third base resin BS3 and third scatterers SCT3.

The third base resin BS3 may include a material having a relatively high light transmittance. The third base resin BS3 may include a transparent organic material.

The third scatterers SCT3 may have a refractive index different from that of the third base resin BS3 and may form an optical interface with the third base resin BS3. In an embodiment, the third scatterers SCT3 may include a light scattering material or light scattering particles that scatter at least a part of transmitted light, for example.

The first and second wavelength-converting units WLC1 and WLC2 and the light-transmitting unit LTU are disposed on the emission material layer EML through the second planarization layer OC2 and the first capping layer CAP1. Therefore, the display device may not desire a separate substrate for the first and second wavelength-converting units WLC1 and WLC2 and the light-transmitting unit LTU.

The second capping layer CAP2 may cover the first and second wavelength-converting units WLC1 and WLC2, the light-transmitting unit LTU, and the first light-blocking member BK1.

The third planarization layer OC3 may be disposed on the second capping layer CAP2 to provide the flat top surfaces of the first and second wavelength-converting units WLC1 and WLC2 and the light-transmitting unit LTU. The third planarization layer OC3 may include an organic material.

The second light-blocking member BK2 may be disposed on the third planarization layer OC3 in the light-blocking area BA. The second light-blocking member BK2 may overlap the first light-blocking member BK1 or the second bank BNK2 in the thickness direction. The second light-blocking member BK2 may block the transmission of light.

The first color filter CF1 may be disposed in the first light-emitting area LA1 on the third planarization layer OC3. The first color filter CF1 may be surrounded by the second light-blocking member BK2. The first color filter CF1 may overlap the first wavelength-converting unit WLC1 in the thickness direction. The first color filter CF1 may selectively transmit light of the first color (e.g., red light) and may block and absorb light of the second color (e.g., green light) and light of the third color (e.g., blue light).

The second color filter CF2 may be disposed on the third planarization layer OC3 in the second light-emitting area LA2. The second color filter CF2 may be surrounded by the second light-blocking member BK2. The second color filter CF2 may overlap the second wavelength-converting unit WLC2 in the thickness direction. The second color filter CF2 may selectively transmit light of the second color (e.g., green light) and may block and absorb light of the first color (e.g., red light) and light of the third color (e.g., blue light).

The third color filter CF3 may be disposed in the third light-emitting area LA3 on the third planarization layer OC3. The third color filter CF3 may be surrounded by the second light-blocking member BK2. The third color filter CF3 may overlap the light-transmitting unit LTU in the thickness direction. The third color filter CF3 may selectively transmit light of the third color (e.g., blue light) and may block and absorb light of the first color (e.g., red light) and light of the second color (e.g., green light).

The first to third color filters CF1, CF2 and CF3 may absorb a part of the light introduced from the outside of the display device to reduce reflection of external light. Accordingly, the first to third color filters CF1, CF2 and CF3 may prevent color distortion due to reflection of external light.

The third passivation layer PAS3 may cover the first to third color filters CF1, CF2 and CF3. The third passivation layer PAS3 may protect the first to third color filters CF1, CF2 and CF3.

The encapsulation layer ENC may be disposed on the third passivation layer PAS3. In an embodiment, the encapsulation layer ENC may include at least one inorganic layer to prevent permeation of oxygen or moisture, for example. In addition, the encapsulation layer ENC may include at least one organic layer to protect the display device from foreign substances such as dust.

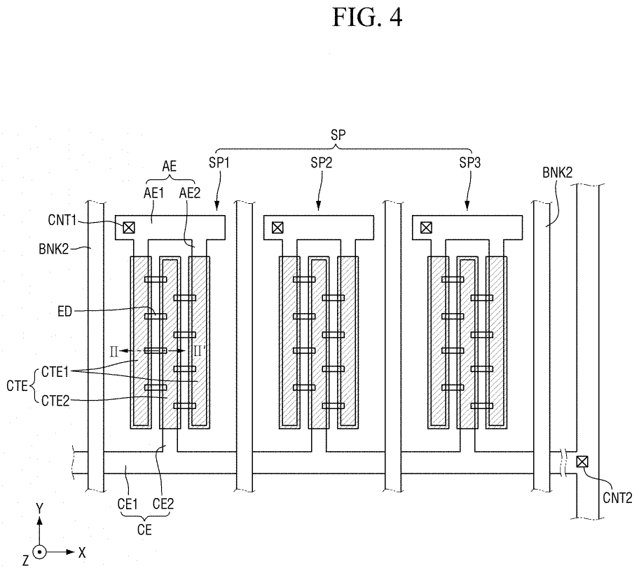

FIG. 4 is a plan view showing an embodiment of a pixel of a display device according to the invention.

Referring to FIG. 4, each of the plurality of pixels may include first to third sub-pixels. The first to third sub-pixels may correspond to the first to third light-emitting areas LA1, LA2 and LA3, respectively. The light-emitting diodes ED of each of the first to third sub-pixels may emit light through the first to third light-emitting areas LA1, LA2 and LA3.

The first to third sub-pixels may emit light of the same color. In an embodiment, each of the first to third sub-pixels may include the light-emitting diodes ED of the same type, and may emit light of the third color or blue light, for example. In another embodiment, the first sub-pixel may emit light of the first color or red light, the second sub-pixel may emit light of the second color or green light, and the third sub-pixel may emit light of the third color or blue light, for example.

Each of the first to third sub-pixels may include first and second electrodes AE and CE, light-emitting diodes ED, a plurality of contact electrodes CTE, and a plurality of second banks BNK2.

The first and second electrodes AE and CE are electrically connected to the light-emitting diodes ED to receive a predetermined voltage, and the light-emitting diodes ED may emit light of a predetermined wavelength band. At least a part of the first and second electrodes AE and CE may form an electric field in the pixel, and the light-emitting diodes ED may be aligned by the electric field.

In an embodiment, the first electrode AE may be a pixel electrode disposed separately in each of the first to third sub-pixels, while the second electrode CE may be a common electrode commonly connected to the first to third sub-pixels, for example. One of the first electrode AE and the second electrode CE may be the anode electrode of the light-emitting diodes ED, while the other may be the cathode electrode of the light-emitting diodes ED.

The first electrode AE may include a first electrode stem AE1 extended in the first direction X, i.e., X1 and X2 (refer to FIGS. 1 and 2), and at least one first electrode branch AE2 branching off from the first electrode stem AE1 and extended in the second direction Y, i.e., Y1 and Y2 (refer to FIGS. 1 and 2).

The first electrode stem AE1 of each of the first to third sub-pixels may be spaced apart from the first electrode stem AE1 of an adjacent sub-pixel, and the first electrode stem AE1 may be disposed on an imaginary extension line with the first electrode stem AE1 of the sub-pixel adjacent in the first direction X1 and X2. The first electrode stems AE1 of the first to third sub-pixels may receive different signals, respectively, and may be driven individually.

The first electrode branch AE2 may branch off from the first electrode stem AE1 and may be extended in the second direction Y. One end of the first electrode branch AE2 may extend from the first electrode stem AE1, while the other end of the first electrode branch AE2 may be spaced apart from a second electrode stem CE1 opposed to the first electrode stem AE1.

The second electrode CE may include the second electrode stem CE1 extended in the first direction X1 and X2, and a second electrode branch CE2 branching off from the second electrode stem CE1 and extended in the second direction Y. The second electrode stem CE1 of each of the first to third sub-pixels may extend from the second electrode stem CE1 of an adjacent sub-pixel. The second electrode stem CE1 may be extended in the first direction X1 and X2 to traverse the plurality of sub-pixels. The second electrode stem CE1 may be connected to a portion extended in a direction at the outer portion of the display area DA or in the non-display area NDA.

The second electrode branch CE2 may be spaced apart from and face the first electrode branch AE2. One end of the second electrode branch CE2 may extend from the second electrode stem CE1, while the other end of the second electrode branch CE2 may be spaced apart from the first electrode stem AE1.

The first electrode AE may be electrically connected to the thin-film transistor layer TFTL (refer to FIG. 3) of the display device through a first contact hole CNT1, and the second electrode CE may be electrically connected to the thin-film transistor layer TFTL of the display device through a second contact hole CNT2. In an embodiment, each of the plurality of first electrode stems AE1 may be disposed in the first contact hole CNT1, and the second electrode stem CE1 may be disposed in the second contact hole CNT2, for example. It is, however, to be understood that the invention is not limited thereto.

The second bank BNK2 may be disposed at the boundary between the pixels. The plurality of first electrode stems AE1 may be spaced apart from one another with respect to the second banks BNK2. The second banks BNK2 may be extended in the second direction Y and may be disposed at the boundaries of the pixels SP including the first to third sub-pixels SP1, SP2 and SP3 arranged in the first direction X1 and X2. Additionally, the second banks BNK2 may be disposed at the boundaries of the pixels SP arranged in the second direction Y as well. The second banks BNK2 may define the boundaries of the plurality of pixels.

When an ink in which the light-emitting diodes ED are dispersed is ejected during the process of fabricating the display device, the second banks BNK2 may prevent the ink from flowing over the boundaries of the pixels SP. The second banks BNK2 may separate the inks in which different light-emitting diodes ED are dispersed so that the inks are not mixed with each other.

The light-emitting diodes ED may be disposed between the first electrode AE and the second electrode CE. One end of the light-emitting diode ED may be connected to the first electrode AE, and the other end of the light-emitting diode ED may be connected to the second electrode CE.

The light-emitting diodes ED may be spaced apart from one another and may be substantially aligned in parallel with one another. The spacing between the light-emitting diodes ED is not particularly limited herein.

The plurality of light-emitting diodes ED may include active layers having the same material as each other so that they may emit light of the same wavelength range or light of the same color. The first to third sub-pixels may emit light of the same color as each other. In an embodiment, the plurality of light-emitting diodes ED may emit light of the third color or blue light having a peak wavelength in the range of about 440 nm to about 480 nm, for example.

The contact electrodes CTE may include first and second contact electrodes CTE1 and CTE2. The first contact electrode CTE1 may cover the first electrode branch AE2 and parts of the light-emitting diodes ED, and may electrically connect the first electrode branch AE2 with the light-emitting diodes ED. The second contact electrode CTE2 may cover the second electrode branch CE2 and other parts of the light-emitting diodes ED, and may electrically connect the second electrode branch CE2 and the light-emitting diodes ED.

The first contact electrode CTE1 may be disposed on the first electrode branch AE2 and extended in the second direction Y. The first contact electrode CTE1 may be in contact with first ends of the light-emitting diodes ED. The light-emitting diodes ED may be electrically connected to the first electrode AE through the first contact electrode CTE1.

The second contact electrode CTE2 may be disposed on the second electrode branch CE2 and extended in the second direction Y. The second contact electrode CTE2 may be spaced apart from the first contact electrode CTE1 in the first direction X1 and X2. The second contact electrode CTE2 may be in contact with second ends of the light-emitting diodes ED. The light-emitting diodes ED may be electrically connected to the second electrode CE through the second contact electrode CTE2.

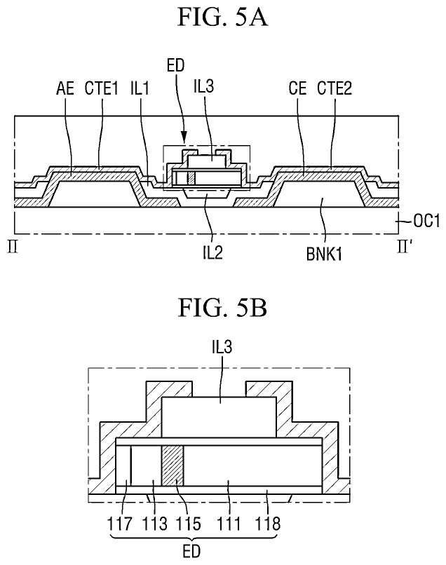

FIG. 5A is a cross-sectional view taken along line II-II′ of FIG. 4, and FIG. 5B is an enlarged plan view of a portion of FIG. 5A.

Referring to FIGS. 5A and 5B, the emission material layer EML (refer to FIG. 3) of the display device may be disposed on the thin-film transistor layer TFTL, and may include first to third insulating layers IL1, IL2 and IL3.

The plurality of first banks BNK1 may be disposed in the first to third light-emitting areas LA1, LA2 and LA3 (refer to FIG. 3), respectively. Each of the plurality of first banks BNK1 may be associated with the first electrode AE or the second electrode CE. Each of the first and second electrodes AE and CE may be disposed on the respective first bank BNK1.

The plurality of first banks BNK1 may be disposed on the first planarization layer OC1, and the side surfaces of each of the plurality of first banks BNK1 may be inclined from the first planarization layer OC1. The inclined surfaces of the first banks BNK1 may reflect light emitted from the light-emitting diodes ED.

Referring to FIGS. 5A and 5B in conjunction with FIG. 4, the first electrode stem AE1 may be disposed in the first contact hole CNT1 penetrating through the first planarization layer OC1. The first electrode stem AE1 may be electrically connected to the thin-film transistor TFT through the first contact hole CNT1.

The second electrode stem CE1 may be extended in the first direction X1 and X2 and may be disposed also in non-light-emitting area where the light-emitting diodes ED are not disposed. The second electrode stem CE1 may be disposed in the second contact hole CNT2 penetrating through the first planarization layer OC1. The second electrode stem CE1 may be electrically connected to a power electrode through the second contact hole CNT2. The second electrode CE may receive a predetermined electric signal from the power electrode.

The first and second electrodes AE and CE may include a transparent conductive material. The first and second electrodes AE and CE may include a conductive material with high reflectivity. The first and second electrodes AE and CE may be made up of a stack of one or more transparent conductive materials and one or more metals having high reflectivity or a single layer including them.

The first insulating layer IL1 may be disposed on the first planarization layer OC1, the first electrode AE, and the second electrode CE. The first insulating layer IL1 may partially cover each of the first and second electrodes AE and CE.

The first insulating layer IL1 may protect the first and second electrodes AE and CE and may insulate the first and second electrodes AE and CE from each other. The first insulating layer IL1 may prevent that the light-emitting diodes ED are in direct contact with other elements and damaged by them.

The light-emitting diodes ED may be disposed between the first electrode AE and the second electrode CE on the first and second insulating layers IL1 and IL2. One end of the light-emitting diode ED may be connected to the first electrode AE, and the other end of the light-emitting diode ED may be connected to the second electrode CE.

The third insulating layer IL3 may be partially disposed on the light-emitting diodes ED disposed between the first electrode AE and the second electrode CE. The third insulating layer IL3 may partially surround the outer surface of the light-emitting diodes ED. The third insulating layer IL3 may protect the light-emitting diodes ED. The third insulating layer IL3 may surround the outer surface of the light-emitting diodes ED.

The contact electrodes CTE may include first and second contact electrodes CTE1 and CTE2. The first contact electrode CTE1 may cover the first electrode branch AE2 and parts of the light-emitting diodes ED, and may electrically connect the first electrode branch AE2 with the light-emitting diodes ED. The second contact electrode CTE2 may cover the second electrode branch CE2 and other parts of the light-emitting diodes ED, and may electrically connect the second electrode branch CE2 and the light-emitting diodes ED.

The first contact electrode CTE1 may be disposed on the first electrode branch AE2 and extended in the second direction Y. The first contact electrode CTE1 may be in contact with first ends of the light-emitting diodes ED. The light-emitting diodes ED may be electrically connected to the first electrode AE through the first contact electrode CTE1.

The second contact electrode CTE2 may be disposed on the second electrode branch CE2 and extended in the second direction Y. The second contact electrode CTE2 may be spaced apart from the first contact electrode CTE1 in the first direction X1 and X2. The second contact electrode CTE2 may be in contact with second ends of the light-emitting diodes ED. The light-emitting diodes ED may be electrically connected to the second electrode CE through the second contact electrode CTE2.

The contact electrodes CTE may include a conductive material.

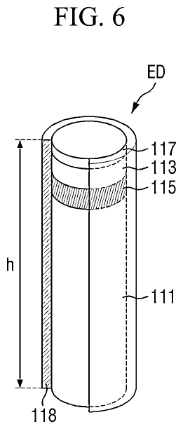

FIG. 6 is a view showing an embodiment of a light-emitting element according to the invention.

Referring to FIG. 6, the light-emitting diode ED is illustrated as a light-emitting diode, but is not limited thereto, and may be other light-emitting semiconductor devices. In an embodiment, the light-emitting diodes ED may have a size of a micro-meter or a nano-meter, and may be an inorganic light-emitting diode including an inorganic material, for example. Inorganic light-emitting diodes may be aligned between two electrodes facing each other by an electric field generated in a particular direction between the two electrodes.

The light-emitting diode ED may have a shape extended in one direction (e.g., vertical direction in FIG. 6) with a height h. The light-emitting diode ED may have a shape of a rod, wire, tube, etc. The light-emitting diode ED may include a first semiconductor layer 111, a second semiconductor layer 113, an active layer 115, an electrode layer 117, and an insulating layer 118.

The first semiconductor layer 111 may be an n-type semiconductor. The second semiconductor layer 113 may be disposed on the active layer 115. Each of the first and second semiconductor layers 111 and 113 may be made up of, but is not limited to, a single layer.

The active layer 115 may be disposed between the first and second semiconductor layers 111 and 113. The active layer 115 may include a material having a single or multiple quantum well structure. When the active layer 115 includes a material having the multiple quantum well structure, quantum layers and well layers may be alternately stacked on one another.

The light emitted from the active layer 115 may exit in the longitudinal direction of the light-emitting diodes ED as well as through both side surfaces. The directivity of light emitted from the active layer 115 may not be limited.

The electrode layer 117 may be an ohmic contact electrode. In another embodiment, the electrode layer 117 may be a Schottky contact electrode. The light-emitting diode ED may include at least one electrode layer 117.

The insulating layer 118 may surround the outer surfaces of the plurality of semiconductor layers and electrode layers. The insulating layer 118 may surround the outer surface of the active layer 115, and may be extended in the direction in which the light-emitting diode ED is extended. The insulating layer 118 may protect the light-emitting diode ED.

The insulating layer 118 may include materials having an insulating property such as silicon oxide (SiOx), silicon nitride (SiNx), silicon oxynitride (SiOxNy), aluminum nitride (AlN) and aluminum oxide (Al₂O₃).

The outer surface of the insulating layer 118 may be subjected to surface treatment. The light-emitting diodes ED may be dispersed in an ink and the ink is sprayed onto the electrode so that the light-emitting diodes ED are aligned during the process of fabricating the display device.

Referring to FIGS. 2A and 2B, in coupling the adjacent ones of the display devices 10-1 to 10-4 together, it is important to ensure a margin for the coupling area between them to hide the sealing member SL for coupling the display devices 10-1 to 10-4 together.

Typically, the sealing member may be perceived when the minimum distance between the light-emitting area groups of the pixels PX adjacent to the sealing member SL (e.g., the minimum distance between the light-emitting area group LA_G of the pixel PX of the first display device 10-1 adjacent to the sealing member SL and the light-emitting area group LA_G of the pixel PX of the second display device 10-2 adjacent to the sealing member SL) is greater than the minimum distance between the light-emitting area groups LA_G of the pixels PX adjacent to each other in a single display device 10-1 or 10-2 by a predetermined value or more.

In order to reduce the minimum distance between the light-emitting area groups of the pixels PX adjacent to the sealing member SL, it has been employed to cut the outer portions of the light-emitting area groups LA_G of the pixels PX adjacent to the sealing member SL. In an embodiment, a part of the outer portion of the light-emitting area group LA_G of the pixel PX of the first display device 10-1 on the side in the first direction X1 (some areas of the non-light-emitting area NLA and the non-display area NDA) and the outer portion of the light-emitting area group LA_G of the pixel PX of the second display device 10-2 on the side in the first direction X2 (some areas of the non-light-emitting area NLA and the non-display area NDA) were cut, for example. In doing so, however, there may be process deviations in cutting the outer portions of the light-emitting area groups LA_G of the pixels PX adjacent to the sealing member SL. In addition, it may be still difficult to ensure a sufficient margin for the coupling area.

In view of the above, in the tiled display in the embodiment of the invention, it is possible to ensure a sufficient margin for the coupling area without cutting the outer portions of the light-emitting area groups LA_G of the pixels PX adjacent to the sealing member SL, by way of disposing the light-emitting area groups LA_G of the pixels PX adjacent to the sealing member SL closest to the sealing member SL in the display area DA to reduce the minimum distance between the light-emitting area groups of the pixels PX adjacent to the sealing member SL as much as possible, and by way of increasing the reference value at which the sealing member SL is perceivable. The reference value at which the sealing member SL is perceivable may be increased by employing a scheme of designing the layout of the light-emitting area groups LA_G of the pixels PX of the tiled display device TD based on predetermined equations, which will be described later.

The layout of the light-emitting area groups LA_G of the pixels PX of the tiled display device TD is not limited to only one display device but may be applied to all of the display devices included in the tiled display device TD.

In an embodiment, the layout of the light-emitting area groups LA_G of the first display device 10-1 may be symmetrical to the layout of the light-emitting area groups LA_G of the second display device 10-2 with respect to a first column line CL that equally divides the sealing member SL disposed between the first display device 10-1 and the second display device 10-2 in the first direction (or row direction), for example. The layout of the light-emitting area groups LA_G of the first display device 10-1 may be symmetrical to the layout of the light-emitting area groups LA_G of the third display device 10-3 with respect to a second row line RL that equally divides the sealing member SL disposed between the first display device 10-1 and the third display device 10-3 in the second direction (or column direction).

Likewise, the layout of the light-emitting area groups LA_G of the fourth display device 10-4 and the layout of the light-emitting area groups LA_G of the third display device 10-3 may be symmetrical to each other with respect to the first column line CL that equally divides the sealing member SL disposed between the fourth display device 10-4 and the third display device 10-3 in the first direction.

In the following descriptions of the layouts of the light-emitting area groups LA_G arranged in the row direction (e.g., the first direction X1 and X2), the layouts of the light-emitting area groups LA_G arranged in the column direction (e.g., the second direction Y1 and Y2) will not be described unless they have to be distinguished from each other specifically.

In addition, the layout of the light-emitting area groups LA_G arranged along the row direction (e.g., the first direction X1 and X2) has a predetermined rule regardless of whether they are in the vicinity of the sealing member SL or within each display device. The layout of the light-emitting area groups LA_G in the vicinity of the sealing member SL will be described first, and then the layout of the light-emitting area groups LA_G in each display device will be described.

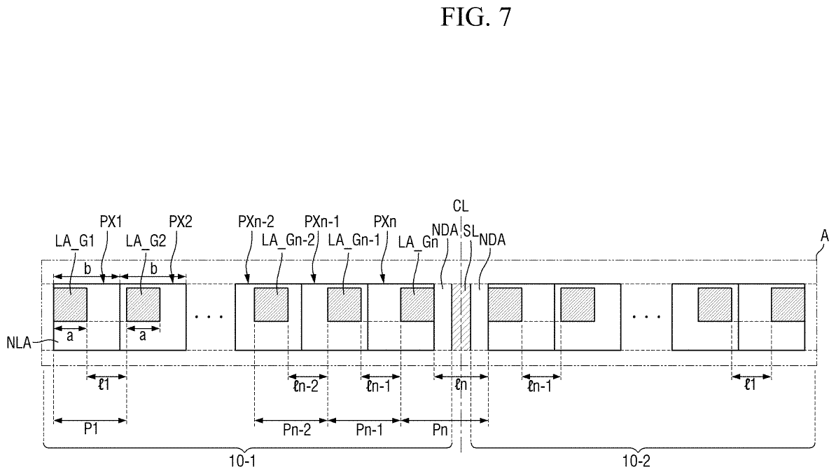

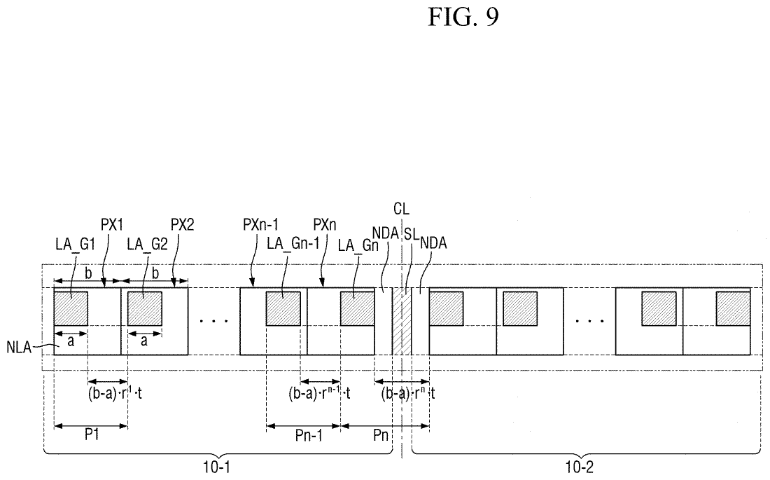

FIG. 7 is an enlarged plan view of area A of FIG. 1. FIG. 9 is a plan view showing an embodiment of FIG. 7.

Area A of FIG. 1 shows pixels in the vicinity of the sealing member SL of the first display device 10-1 and the second display device 10-2. As described above, the layout of the light-emitting area groups LA_G of the first display device 10-1 is symmetrical to the layout of the light-emitting area groups LA_G of the second display device 10-2 with respect to the first column line CL that equally divides the sealing member SL disposed between the first display device 10-1 and the second display device 10-2 in the second direction. Referring to FIG. 7, the pixels PX of the first display device 10-1 may include a first pixel PX1, a second pixel PX2 disposed adjacent to one side of the first pixel PX1 in the first direction X1, the (n-1)^{th} pixel PXn-1 spaced apart from the side of the second pixel PX2 in the first direction Xl, and the n^{th} pixel PXn adjacent to one side of the (n-1)^{th} pixel PXn-1 in the first direction Xl, where n is a natural number equal to or greater than four. The pixels PX of the second display device 10-2 may include the n^{th} pixel PXn that is spaced apart from the n^{th} pixel PXn of the first display device 10-1 with the sealing member SL therebetween.

FIG. 7 merely shows an embodiment of the pixels PX of the first display device 10-1 adjacent to the sealing member SL, and the number of the pixels PX shown in FIG. 7 is not limited thereto. That is to say, when n is 4, the first to fourth pixels PX1 to PX4 may be disposed, and when n is 5, the first to fifth pixels PX1 to PX5 may be disposed.

The pixels PX1, PX2, PXn-2, PXn-1 and PXn may have the same shape and size as each other. In an embodiment, each of the pixels PX1, PX2, PXn-2, PXn-1 and PXn may have a quadrangular (e.g., rectangular) shape including first sides extended in the first direction and second sides extended in the second direction, for example. The length of the first side extended in the first direction may be equal to b. It is to be understood that the shape of the pixels PX1, PX2, PXn-2, PXn-1 and PXn may have other shapes than a rectangle, such as Pentile, an oval, a circle and other polygons. Moreover, the pixels PX1, PX2, PXn-2, PXn-1 and PXn may have the same shape as each other but are not limited thereto, and may have different sizes from each other in alternative embodiment.

The pixels PX1, PX2, PXn-2, PXn-1 and PXn include the light-emitting area groups LA_G1, LA_G2, LA Gn-2, LA Gn-1 and LA Gn, respectively. The shape of the light-emitting area groups LA_G1, LA G2, LA_Gn-2, LA Gn-1 and LA Gn may conform to the shape of the respective pixels. Accordingly, each of the light-emitting area groups LA_G1, LA_G2, LA_Gn-2, LA Gn-1 and LA Gn may have a quadrangular (e.g., rectangular) shape including first sides extended in the first direction and second sides extended in the second direction. The length of the first side extended in the first direction may be equal to a that is smaller than b.

The light-emitting area groups LA_G1, LA G2, LA Gn-2, LA Gn-1 and LA Gn are continuously arranged along the row direction (or the first direction). Adjacent ones of the light-emitting area groups LA_G1, LA_G2, LA_Gn-2, LA_Gn-1 and LA_Gn have predetermined minimum distances 11, In-2, In-1 and In in the row direction (or first direction), and adjacent ones of the light-emitting area groups LA_G1, LA_G2, LA_Gn-2, LA Gn-1 and LA_Gn are arranged in the row direction (or first direction) with predetermined pitches P1, Pn-2, Pn-1 and Pn.

The minimum distance between the light-emitting area groups LA_G1, LA_G2, LA_Gn-2, LA_Gn-1 and LA Gn that are continuously arranged in the row direction (or the first direction) of the first display device 10-1 gradually increases, and then the minimum distance between the light-emitting area groups LA_Gn, LA_Gn-1, LA_Gn-2, LA_G2 and LA_G1 that are continuously arranged in the row direction (or the first direction) of the second display device 10-2 gradually decreases again from the sealing member SL.

The minimum distance ln between the light-emitting area group LA_Gn of the n^{th} pixel PXn of the first display device 10-1 and the light-emitting area group LA_Gn of the n^{th} pixel PXn of the second display device 10-2 (hereinafter referred to as the n^{th} minimum distance) may be greater than the minimum distance ln-2 between the light-emitting area group LA_G(n-2) of the (n-2)^{th} pixel PXn-2 of the first display device 10-1 and the light-emitting area group LA_Gn-1 of the (n-1)^{th} pixel PXn-1 of the first display device 10-1 (hereinafter referred to as the (n-2)^{th} minimum distance) and the minimum distance ln-1 between the light-emitting area group LA_Gn-1 of the (n-1)^{th} pixel PXn-1 of the first display device 10-1 and the light-emitting area group LA_Gn of the n^{th} pixel PXn of the first display device 10-1 (hereinafter referred to as the (n-1)^{th} minimum distance), and the (n-1)^{th} minimum distance ln-1 may be greater than the (n-2)^{th} minimum distance ln-2.

The (n-2)^{th} minimum distance ln-2, the (n-1)^{th} minimum distance ln-1, and the n^{th} minimum distance ln are determined based on a predetermined relational expression. The relational expression may include sequences or functions that satisfy a condition that prevents differences in the distance between the light-emitting area groups from being perceived when the light-emitting area groups are arranged based on the relational expression. In an embodiment, the relational expression may include, but is not limited to, a geometric sequence, an arithmetic sequence, a natural logarithmic function, a natural exponential function, etc., for example. Any other relational expressions well known in the art that satisfy the above condition may be employed. In the following description, an example where the relational expression is a geometric sequence will be described below.

Referring to FIG. 9, in an embodiment of the invention, the (n-2)^{th} minimum distance In-2, the (n-1)^{th} minimum distance In-1, and the n^{th} minimum distance In are determined based on Equation 1 below:

lk=(b−a)*t*r\hat{ }k [Equation 1]

where r denotes a rational number greater than 1 and less than 2, t denotes a rational number greater than 0 and less than 1, k denotes the numbering index of a pixel that is disposed on the opposite side in the row direction among adjacent light-emitting area groups, b denotes the width of each pixel in the row direction, and a denotes the width of each light-emitting area group.

That is to say, the (n-2)^{th} minimum distance ln-2, the (n-1)^{th} minimum distance ln-1, and the n^{th} minimum distance In may increase in the first direction X1 in a geometric sequence.

In the tiled display in the embodiment of the invention, the (n-2)^{th} minimum distance ln-2, the (n-1)^{th} minimum distance ln-1 and the n^{th} minimum distance In are designed based on Equation 1 above, so that the minimum distance line between the n^{th} light-emitting area group LA_Gn of the n^{th} pixel PXn of the first display device 10-1 and the light-emitting area group LA_Gn of the n^{th} pixel PXn of the second display device 10-2 may be increased, and the light-emitting area groups may be arranged in the row direction. Accordingly, it is possible to prevent the differences in the distance between the light-emitting area groups from being perceived, and thus a sufficient margin for the coupling area may be obtained.

In other embodiments, the (n-2)^{th} minimum distance ln-2 and the (n-1)^{th} minimum distance In-1 of a tiled display may be designed based on Equation 1 above, the (n-1)^{th} minimum distance In-1 may be equal to the n^{th} minimum distance ln, and the (n-1)^{th} minimum distance In-1 of the second display device 10-2 may be equal to the (n-2)^{th} minimum distance ln-2 of the first display device 10-1. According to the above-described some embodiments, the (n-2)^{th} minimum distance In-2, the (n-1)^{th} minimum distance ln-1 and the n^{th} minimum distance In are determined based on Equation 2 below:

lk=(b−a)−t+r*(k−1) [Equation 2]

where r denotes a rational number greater than 0, t denotes a rational number greater than 0 and less than 0.5, k denotes the numbering index of a pixel that is disposed on the opposite side in the row direction among adjacent light-emitting area groups, b denotes the width of each pixel in the row direction, and a denotes the width of each light-emitting area group.

That is to say, the (n-2)^{th} minimum distance ln-2, the (n-1)^{th} minimum distance ln-1 and the n^{th} minimum distance ln may increase in the first direction X1 in an arithmetic sequence.

According to the above-described other embodiments, the (n-2)^{th} minimum distance ln-2, the (n-1)^{th} minimum distance ln-1 and the n^{th} minimum distance ln are determined based on Equation 3 below:

lk=(b−a)−t+(b−a)*e\hat{ }(k*r) [Equation 3]

where r denotes a rational number greater than 1 and less than 2, t denotes a rational number greater than 0 and less than 0.5, k denotes the numbering index of a pixel that is disposed on the opposite side in the row direction among adjacent light-emitting area groups, b denotes the width of each pixel in the row direction, and a denotes the width of each light-emitting area group.

That is to say, the (n-2)^{th} minimum distance ln-2, the (n-1)^{th} minimum distance ln-1 and the n^{th} minimum distance ln may increase in the first direction X1 as a natural exponential function.

According to the above-described still other embodiments, the (n-2)^{th} minimum distance ln-2, the (n-1)^{th} minimum distance ln-1 and the n^{th} minimum distance ln are determined based on Equation 4 below:

lk=(b−a)−t+(b−a)*ln(k*t) [Equation 4]

where r denotes a rational number greater than 1 and less than 2, t denotes a rational number greater than 0 and less than 1, k denotes the numbering index of a pixel that is disposed on the opposite side in the row direction among adjacent light-emitting area groups, b denotes the width of each pixel in the row direction, and a denotes the width of each light-emitting area group.

That is to say, the (n-2)^{th} minimum distance In-2, the (n-1)^{th} minimum distance ln-1 and the n^{th} minimum distance In may increase in the first direction X1 as a natural logarithmic function.

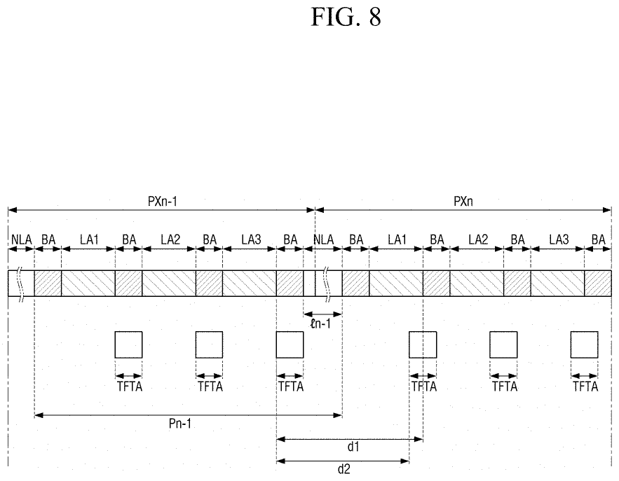

FIG. 8 is a schematic view showing an embodiment of layouts between light-emitting areas and transistor areas of pixels according to the invention.

Referring to FIGS. 7 and 8, the light-emitting area groups LA_G may include transistor areas TFTA in which transistors TFT (refer to FIG. 3) connected to the pixels PX are disposed, and the minimum distance between the transistor areas TFTA of adjacent pixels PX may be maintained.

The minimum distance between light-emitting area groups may vary (increase or decrease) along the row direction with a predetermined relational expression, as described above with reference to FIG. 7. As shown in FIG. 8, the transistor areas TFTA may generally overlap with the light-blocking areas BA, respectively, and the minimum distance between the light-emitting area groups varies (increases or decreases) along the row direction with a predetermined relational expression. Accordingly, the minimum distance d2 between the adjacent transistor areas TFTA is maintained, while the minimum distance dl from the boundary between the third light-emitting area LA3 and the light-blocking area BA of the (n-1)^{th} pixel PXn-1 to the boundary between the first light-emitting area LA1 and the light-blocking area BA of the n^{th} pixel PXn is different from the minimum distance d2 between adjacent transistor areas TFTA. According to the example shown in FIG. 8, the minimum distance d1 from the boundary between the third light-emitting area LA3 and the light-blocking area BA of the (n-1)^{th} pixel PXn-1 to the boundary between the first light-emitting area LA1 and the light-blocking area BA of the n^{th} pixel PXn may greater than the minimum distance d2 between adjacent transistor areas TFTA.

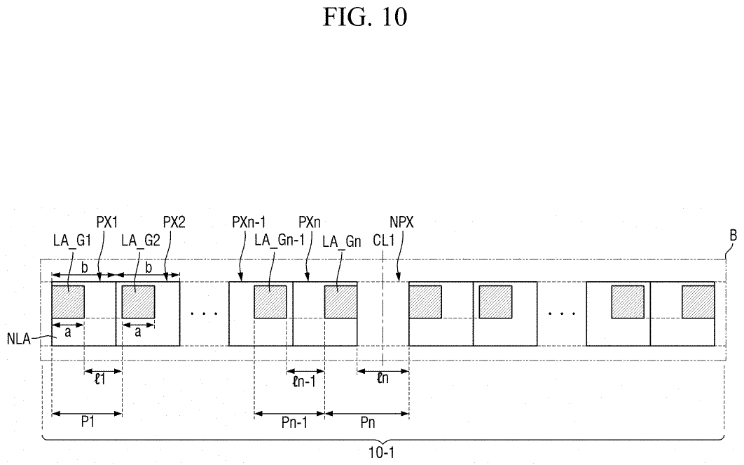

FIG. 10 is an enlarged plan view of area B of FIG. 1.

Hereinafter, a layout of the light-emitting area groups LA_G in each display device will be described with reference to FIG. 10. The layout of the light-emitting area groups LA_G in the display device is substantially identical to that of the light-emitting area groups LA_G of the pixels PX adjacent to the sealing member SL in the first display device 10-1 described above with reference to FIG. 7 except for some differences.

Referring to FIG. 10, in an embodiment of the invention, the (n-2)^{th} minimum distance ln-2, the (n-1)^{th} minimum distance ln-1 and the n^{th} minimum distance ln of the light-emitting area groups LA_G in the first display device 10-1 are determined based on Equation 1 above.

It is to be noted that the layout of the light-emitting area groups LA_G in the first display device 10-1 is different in that a non-pixel NPX is disposed at the location where the sealing member SL and the non-display area NDA are disposed in the layout of the light-emitting area groups LA_G of the pixels PX adjacent to the sealing member SL. The non-pixel NPX may have the same configuration as the non-light-emitting area NDA of the pixel PX.

In the tiled display device TD in the embodiment, the (n-2)^{th} minimum distance ln-2, the (n-1)^{th} minimum distance ln-1 and the n^{th} minimum distance ln may be designed in the same manner as the layout of the light-emitting area groups LA_G of the pixels PX adjacent to the sealing member SL based on Equation 1 above even in the display devices. Accordingly, it is possible to prevent differences in the distance between light-emitting area groups arranged along the row direction from being perceived even in each display device.

Hereinafter, an embodiment of a tiled display device TD in an embodiment will be described in detail.

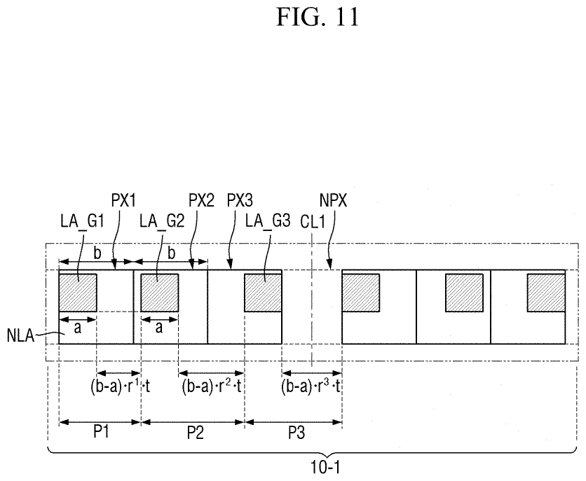

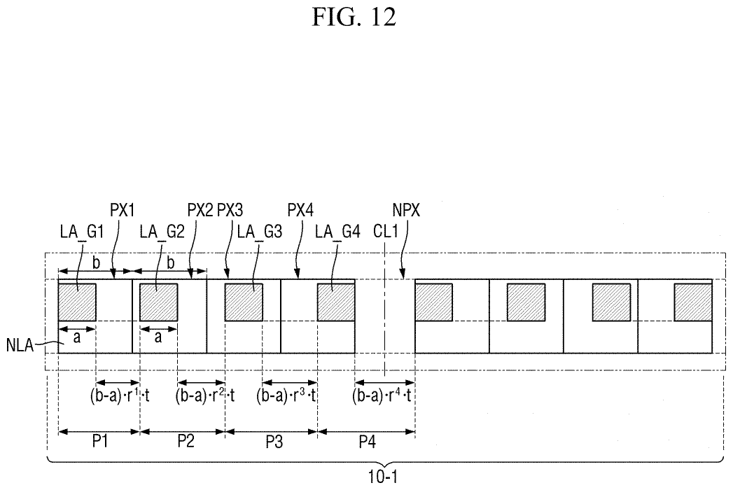

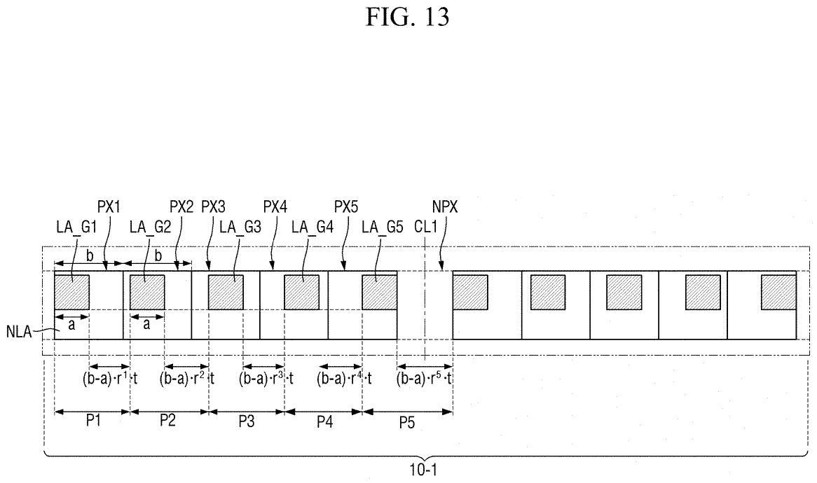

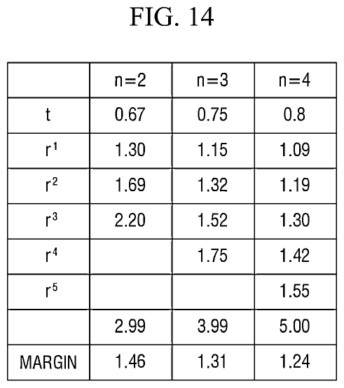

FIG. 11 is a plan view showing an embodiment of FIG. 10. FIG. 12 is a plan view showing another embodiment of FIG. 10. FIG. 13 is a plan view showing yet another embodiment of FIG. 10. FIG. 14 is a table showing coefficients for Equation of distances between adjacent light-emitting area groups versus the number of pixels according to the embodiments of FIGS. 11 to 13.

FIG. 11 shows a layout of the light-emitting area groups LA_G1 to LA_G3 when n is 3, FIG. 12 shows a layout of the light-emitting area groups LA_G1 to LA_G4 when n is 4, and FIG. 13 shows a layout of the light-emitting area groups LA_G1 to LA G4 when n is 5.

In FIG. 11, the light-emitting area groups LA_G1 to LA_G3 adjacent along the row direction are arranged with the minimum distances (b−a)*t*r\hat{ }1, (b−a)*t*r\hat{ }2 and (b−a)*t*r\hat{ }3, and pitches P1, P2 and P3, respectively. In FIG. 12, the light-emitting area groups LA_G1 to LA_G4 adjacent along the row direction are arranged with the minimum distances (b−a)*t*r\hat{ }1, (b−a)*t*r\hat{ }2, (b−a)*t*r\hat{ }3 and (b−a)*t*r\hat{ }4, and pitches P1, P2, P3 and P4, respectively. In FIG. 13, the light-emitting area groups LA_G1 to LA_G5 adjacent along the row direction are arranged with the minimum distances (b−a)*t*r\hat{ }1, (b−a)*t*r\hat{ }2, (b−a)*t*r\hat{ }3, (b−a)*t*r\hat{ }4 and (b−a)*t*r\hat{ }5 and pitches P1, P2, P3, P4 and P5, respectively.

In each of FIGS. 11 to 13, the layout of the light-emitting area groups in the first display device 10-1 is symmetrical with respect to a column line CL1 that equally divides the non-pixel NPX in the row direction and extended in the column direction.

As shown in FIG. 14, the value of r may vary depending on the value of n. In an embodiment, when n is 2, r is 1.3 and t is 0.67, when n is 3, r is 1.15 and t is 0.75, and when n is 4, r is 1.09 and t is 0.8, for example. The values of r and t are determined based on the value of n. Specifically, the values of r and t are determined according to Equation 5 below:

n=(r1+ . . . +m−1+m)*t [Equation 5]

Specifically, when n is 2, the values of r and t are determined to satisfy (r1+r2)*t=2. The determined value of r is 1.3 and the determined value of t is 0.67.

When n is 3, the values of r and t are determined to satisfy (r1+r2+r3)*t=3. The determined value of r is 1.15 and the determined value oft is 0.75.

When n is 4, the values of r and t are determined to satisfy (rl+r2+r3 +r4)*t=4. The determined value of r is 1.09 and the determined value of t is 0.8.

It may be seen that the values of r and t approximate to 1 as the value of n increases.

In particular, when the value of r becomes smaller to approximate to 1, in Equation 1 above, the minimum distance between the light-emitting area group LA_Gn of the n^{th} pixel PXn of the first display device 10-1 and the light-emitting area group LA_Gn of the n^{th} pixel PXn of the second display device 10-2 becomes smaller accordingly. That is to say, the margin for the coupling area between adjacent display devices is reduced. Therefore, it is desired that n is equal to or less than 50 in order to ensure a sufficient margin for the coupling area.

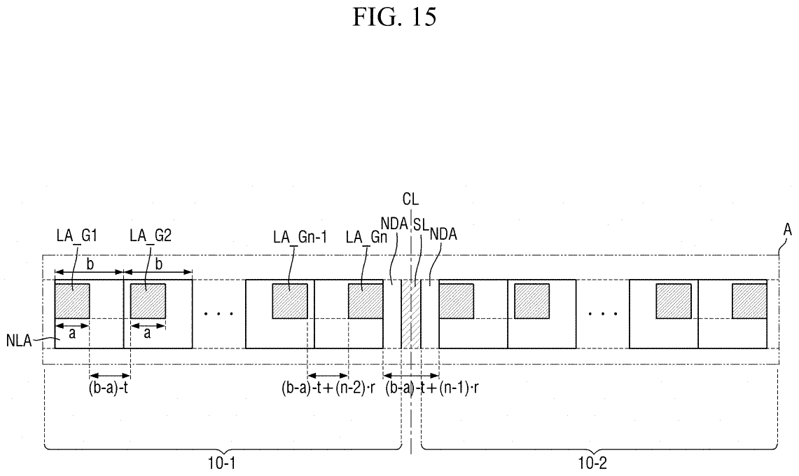

FIG. 15 is a plan view showing another embodiment of FIG. 9.

FIG. 15 shows an example where a geometric sequence is employed as a relational expression that satisfies a condition that prevents differences in the distance between light-emitting area groups from being perceived.

Referring to FIG. 15, in an embodiment of the invention, the (n-2)^{th} minimum distance ln-2, the (n-1)^{th} minimum distance ln-1, and the n^{th} minimum distance ln are determined based on Equation 2 above. Equation 2 has been described above, and therefore, the redundant descriptions will be omitted.

In the tiled display in the embodiment of the invention, the (n-2)^{th} minimum distance ln-2, the (n-1)^{th} minimum distance ln-1 and the n^{th} minimum distance ln are designed based on Equation 3 above, so that the minimum distance line between the n^{th} light-emitting area group LA_Gn of the n^{th} pixel PXn of the first display device 10-1 and the light-emitting area group LA_Gn of the n^{th} pixel PXn of the second display device 10-2 may be increased, and the light-emitting area groups may be arranged in the row direction. Accordingly, it is possible to prevent the differences in the distance between the light-emitting area groups from being perceived, and thus a sufficient margin for the coupling area may be obtained.

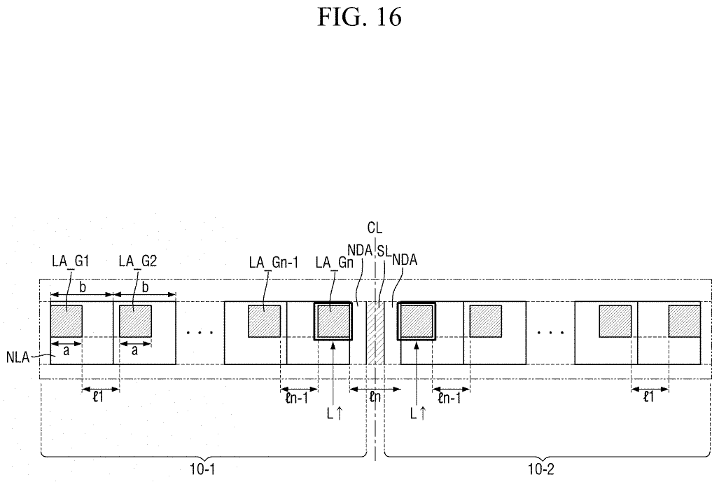

FIG. 16 is a schematic view showing adjusting the luminance of light-emitting area groups adjacent to a boundary between display devices.

As described above with reference to FIGS. 1 to 15, in order to prevent the sealing member SL disposed at the coupling area between adjacent display devices from being perceived, the layout of the light-emitting area groups LA__G of the pixels PX of the tiled display device TD is designed based on the equations (Equation 1 or 4) as a scheme that increases the reference value at which the sealing member SL is perceivable.

According to the embodiment of FIG. 16, in order to prevent the sealing member SL disposed at the coupling area between adjacent display devices from being perceived, the layout may be designed so that the luminance L of the light-emitting area groups adjacent to the sealing member SL in the display devices 10-1 and 10-2 is higher than a reference luminance.

By doing so, it is possible to prevent the sealing member SL disposed at the coupling area between the adjacent display devices 10-1 and 10-2 from being perceived.

The other elements of the embodiment of FIG. 16 are substantially identical to those of the embodiment described above with reference to FIG. 7, and therefore, the redundant descriptions will be omitted.

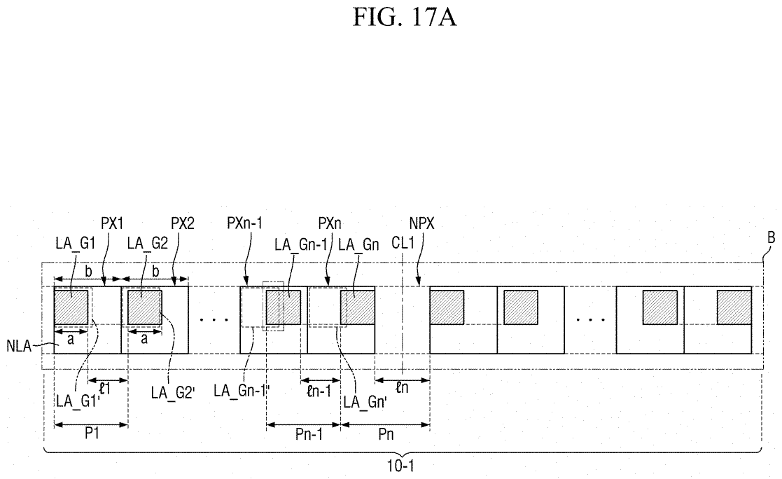

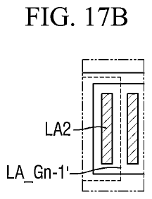

FIG. 17A is a plan view showing an embodiment of a layout of a second light-emitting area of a light-emitting area group, and FIG. 17B is an enlarged plan view of a portion of FIG. 17A.

Referring to FIGS. 17 and 17B in conjunction with FIGS. 2A and 2B, an example is depicted where the layout of the light-emitting areas LA1, LA2 and LA3 in light-emitting area groups having a large minimum distance between adjacent light-emitting area groups may be changed in a tiled display according to this embodiment.

More specifically, FIGS. 17A and 17B show light-emitting area groups LA_G1′, LA_G2′, LA_Gn-1′ and LA Gn′ of pixel PX1, PX2, PXn-1 and PXn, respectively, which are designed in an existing scheme. Although not limited thereto, the light-emitting area groups having a smaller minimum distance therebetween (e.g., LA_G1 and LA_G2) have moved rarely or by a small distance from the light-emitting area groups LA_G1′ and LA_G2′ designed according to the existing scheme. The light-emitting area groups having a larger minimum distance therebetween (e.g., LA_Gn-1 and LA_Gn) have moved more from the light-emitting area groups LA_Gn-1′ and LA_Gn′ designed according to the existing scheme.

In other words, the non-light-emitting area NLA between the light-emitting area groups LA_Gn-1, LA_Gn may be perceived because they have a larger distance therebetween.

In order to prevent this, according to this embodiment, a second light-emitting area LA2 of the light-emitting area groups LA_Gn-1 and LA_Gn may be disposed in a location where the light-emitting area groups LA_Gn-1′ and LA_Gn' designed according to the existing scheme and the light-emitting area groups (e.g., LA_Gn-1 and LA_Gn) overlap each other. Green light exits through the second light-emitting area LA2. The green light is more likely to be perceived than blue light and red light, and thus it is possible to suppress the non-light-emitting area NLA between the light-emitting area groups LA_Gn-1 and LA_Gn from being perceived.

In this structure, the pitch of the second light-emitting areas LA2 may be maintained.

The other elements of the embodiment of FIGS. 17A and 17B are substantially identical to those of the embodiment described above with reference to FIG. 7, and therefore, the redundant descriptions will be omitted.

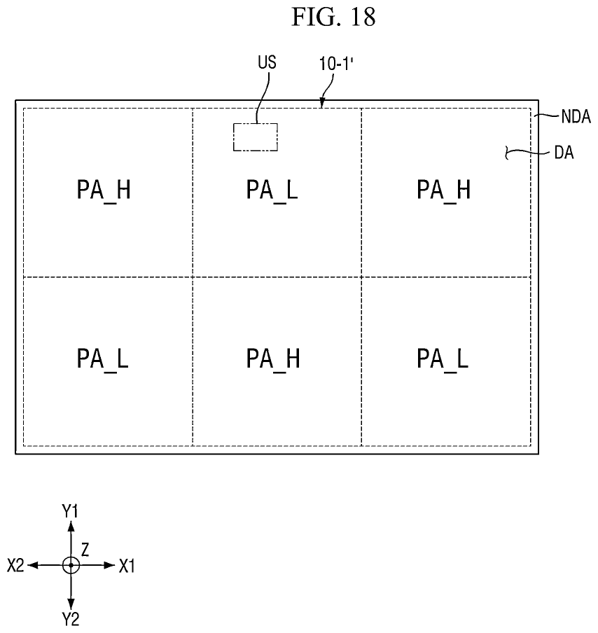

FIG. 18 is a plan view showing an example where a sensor is employed.

Referring to FIG. 18, pixels of a first display device 10-1′ may have different densities at different areas. The pixels of the first display device 10-1′ may include high-density pixel areas PA_H having a high density of pixels, and low-density pixel areas PA_L having a low density than that of the high-density pixel areas PA_H. The high-density pixel areas PA_H and the low-density pixel areas PA_L may be alternately arranged along the first and second directions X1 and X2 and Y1 and Y2 as shown in FIG. 18, but the invention is not limited thereto. They may be arranged in various ways.

The tiled display may further include a sensor US disposed under the first display device 10-1′. The sensor US may be disposed under the display panel. The sensor US may include a camera, a fingerprint on display (“FOD”), a sound on display (“SOD”), etc. as desired. The camera may include an under panel camera (“UPC”).

The sensor US may be disposed to overlap the low-density pixel areas PA_L in the thickness direction. The pitch of the pixels in the high-density pixel areas PA_H is smaller than that of the pixels in the low-density pixel areas PA_L. In other words, the pitch of the pixels in the low-density pixel areas PA_L is greater than the pitch of the pixels in the high-density pixel areas PA_H.

The sensor US is disposed to overlap the low-density pixel area PA_L having a larger pitch of pixels, so that more light may be received by the sensor US.

As the pitch of the pixels is larger, the pitch between the light-emitting area groups of the pixels is also larger, and thus it is more likely that the non-light-emitting area, which is the space between adjacent light-emitting area groups is perceived in the low-density pixel areas PA_L.

In view of the above, according to this embodiment, by employing the layout scheme between the light-emitting area groups described above with reference to FIG. 10 to the low-density pixel areas PA_L, it is possible to prevent the non-light-emitting area from being perceived between adjacent light-emitting area groups.

Although embodiments of the invention have been disclosed for illustrative purposes, those skilled in the art will appreciate that various modifications, additions and substitutions are possible, without departing from the scope and spirit of the invention as disclosed in the accompanying claims.

What is claimed is:

1. A display device comprising:
a display area comprising a plurality of pixels arranged in a first direction and a second direction intersecting the first direction, each of the plurality of pixels comprising:
light-emitting area groups and non-light-emitting areas disposed adjacent to the light-emitting area groups; and
a non-display area surrounding the display area,
wherein a minimum distance between adjacent ones of the light-emitting area groups continuously arranged along the first direction or the second direction increases and decreases repeatedly.

2. The display device of claim 1, wherein the plurality of pixels of the display device comprises:
an (n-2)^{th} pixel, an (n-1)^{th} pixel adjacent to one side of the (n-2)^{th} pixel in the first direction; and
an n^{th} pixel adjacent to one side of the (n-1)^{th} pixel in the first direction,
wherein a minimum distance between the light-emitting area group of the (n-1)^{th} pixel of the display device and the light-emitting area group of the n^{th} pixel of the display device is greater than a minimum distance between the light-emitting area group of the (n-2)^{th} pixel of the display device and the light-emitting area group of the (n-1)^{th} pixel of the display device, wherein n is equal to or greater than 3.

3. The display device of claim 2, wherein a minimum distance lk between the light-emitting area groups of the (n-2)^{th} pixel, the (n-1)^{th} pixel and the n^{th} pixel of the display device is based on a following equation:
lk=(b−a)*t*r\hat{ }k
where r denotes a rational number greater than 1 and less than 2, t denotes a rational number greater than 0 and less than 1, k denotes a numbering index of a pixel which is disposed on an opposite side in the first direction among adjacent light-emitting area groups, b denotes a width of each pixel in the first direction, and a denotes a width of each light-emitting area group.

4. The display device of claim 2, wherein a minimum distance lk between the light-emitting area groups of the (n-2)^{th} pixel, the (n-1)^{th} pixel and the n^{th} pixel of the display device is based on a following equation:
lk=(b−a)−t+r*(k−1)
where r denotes a rational number greater than 0, t denotes a rational number greater than 0 and less than 0.5, k denotes a numbering index of a pixel which is disposed on an opposite side in the first direction among adjacent light-emitting area groups, b denotes a width of each pixel in the first direction, and a denotes a width of each light-emitting area group.

5. The display device of claim 2, wherein a minimum distance lk between the light-emitting area groups of the (n-2)^{th} pixel, the (n-1)^{th} pixel and the n^{th} pixel of the display device is based on a following equation:
lk=(b−a)−t+(b−a)*e\hat{ }(k*r)
where r denotes a rational number greater than 1 and less than 2, t denotes a rational number greater than 0 and less than 0.5, k denotes a numbering index of a pixel which is disposed on an opposite side in the first direction among adjacent light-emitting area groups, b denotes a width of each pixel in the first direction, and a denotes a width of each light-emitting area group.

6. The display device of claim 2, wherein a minimum distance lk between the light-emitting area groups of the (n-2)^{th} pixel, the (n-1)^{th} pixel and the n^{th} pixel of the display device is based on a following equation:
lk=(b−a)−t+(b−a)*ln(k*r)
where r denotes a rational number greater than 1 and less than 2, t denotes a rational number greater than 0 and less than 1, k denotes a numbering index of a pixel which is disposed on an opposite side in the first direction among adjacent light-emitting area groups, b denotes a width of each pixel in the first direction, and a denotes a width of each light-emitting area group.

7. The display device of claim 1, further comprising:
a high-density pixel area having a first density of pixels of the plurality of pixels; and
a low-density pixel area having a second density of pixels of the plurality of pixels less than the first density of the high-density pixel area,
wherein the display device further comprises a sensor disposed under the display device, and
wherein the sensor overlaps the low-density pixel area in a third direction perpendicular to the first and second directions.

8. The display device of claim 7, wherein a minimum distance between the light-emitting area groups of the pixels disposed in the low-density pixel area overlapping the sensor increases and decreases repeatedly.

9. The display device of claim 8, wherein the sensor comprises an UPC, FOD, or SOD.

10. The display device of claim 1, wherein each of the light-emitting area groups comprise a first light-emitting area which emits red light, a second light-emitting area which emits green light, a third light-emitting area which emits blue light, and a non-light-emitting area disposed between adjacent ones of the light-emitting areas.

11. The display device of claim 10, a pitch of the second light-emitting areas of adjacent ones of the plurality of pixels is maintained to improve visibility.

12. The display device of claim 10, wherein each of the light-emitting areas comprises an inorganic light-emitting element.

13. The display device of claim 10, wherein the light-emitting area groups comprise transistor areas in which transistors connected to the plurality of pixels are disposed, and
wherein a minimum distance between the transistor areas of the plurality of pixels is maintained.

14. A display device comprising:
a first display device;
a second display device disposed on one side of the first display device; and
a sealing member disposed between the first display device and the second display device and coupling the first display device with the second display device, each of the first display device and the second display device comprising:
a display area comprising a plurality of pixels arranged in a first direction and a second direction intersecting the first direction, each of the plurality of pixels comprising:
light-emitting area groups and non-light-emitting areas disposed adjacent to the light-emitting area groups; and
a non-display area surrounding the display area,
wherein a minimum distance between adjacent ones of the light-emitting area groups continuously arranged along the first direction or the second direction increases and decreases repeatedly.

15. The display device of claim 14, wherein a minimum distance between the light-emitting area groups arranged continuously along the first direction of the first and second display devices increases and decreases repeatedly.

16. The display device of claim 15, wherein the plurality of pixels of the first display device comprises an (n-2)^{th} pixel, an (n-1)^{th} pixel adjacent to one side of the (n-2)^{th} pixel in the first direction, and an n^{th} pixel adjacent to one side of the (n-1)^{th} pixel in the first direction,
wherein the plurality of pixels of the second display device comprises an n^{th} pixel adjacent to one side of the n^{th} pixel of the first display device in the first direction, and
wherein a minimum distance between the light-emitting area group of the n^{th} pixel of the first display device and the light-emitting area group of the n^{th} pixel of the second display device is greater than a minimum distance between the light-emitting area group of the (n-2)^{th} pixel of the first display device and the light-emitting area group of the (n-1)^{th} pixel of the first display device, and a minimum distance between the light-emitting area group of the (n-1)^{th} pixel of the first display device and the light-emitting area group of the n^{th} pixel of the first display device, wherein n is equal to or greater than 3.

17. The display device of claim 16, wherein the n^{th} pixel of the first display device is spaced apart from the n^{th} pixel of the second display device with the sealing member therebetween.

18. The display device of claim 17, wherein the minimum distance between adjacent ones of the light-emitting area groups of the (n-2)^{th} pixel, the (n-1)^{th} pixel and the n^{th} pixel of the first display device and the minimum distance between the light-emitting area group of the n^{th} pixel of the first display device and the light-emitting area group of the n^{th} pixel of the second display device have a relationship of a geometric sequence, an arithmetic sequence, an exponential function or a logarithmic function.

19. The display device of claim 18, wherein a layout of the (n-2)^{th} pixel, the (n-1)^{th} pixel and the n^{th} pixel of the first display device is symmetrical to a layout of the (n-2)^{th} pixel, the (n-1)^{th} pixel and n^{th} pixel of the second display device with respect to the sealing member.

20. The display device of claim 16, wherein a margin between the light-emitting area group of the n^{th} pixel of the first display device and the light-emitting area group of the n^{th} pixel of the second display device is obtainable as the minimum distance between the light-emitting area groups arranged continuously along the first direction of the first and second display devices increases and decreases repeatedly.

21. The display device of claim 14, further comprising:
a third display device disposed on an opposite side of the first display device; and
a fourth display device disposed on an opposite side of the second display device, each of the third display device and the fourth display device comprising:
a display area comprising a plurality of pixels arranged in a first direction and a second direction intersecting the first direction, each of the plurality of pixels comprising:
light-emitting area groups and non-light-emitting areas disposed adjacent to the light-emitting area groups; and
a non-display area surrounding the display area,
wherein the sealing member is further disposed between the first display device and the third display device, between the second display device and the fourth display device, and between the third display device and the fourth display device,
wherein a minimum distance between adjacent ones of the light-emitting area groups continuously arranged along the first direction or the second direction increases and decreases repeatedly,
wherein a layout of the light-emitting area groups of the first display device and a layout of the light-emitting area groups of the fourth display device are symmetrical to each other, and
wherein a layout of the light-emitting area groups of the second display device and a layout of the light-emitting area groups of the third display device are symmetrical to each other.
